(19) United States
(12) Patent Application Publication
(10) Pub. No.: US 2026/0286531 A1
(43) Pub. Date: Sep. 24, 2026

(54) ATOMIC LAYER ETCHING METHOD FOR METAL OXIDE FILM

(71) Applicant: SK SPECIALTY CO., LTD., Yeongjun-si, Gyeongsangbuk-do (KR)

(72) Inventors: Sung Woong CHUNG, Sejong (KR); Jung Hun KWAK, Sejong (KR); Byung Hyang KWON, Sejong (KR); Yong Jun CHO, Sejong (KR)

(73) Assignee: SK SPECIALTY CO., LTD., Yeongjun-si, Gyeongsangbuk-do (KR)

(21) Appl. No.: 18/873,737

(22) PCT Filed: Jul. 5, 2023
(86) PCT No.: PCT/KR2023/009514

§ 371 Date: Dec. 11, 2024

(30) Foreign Application Priority Data
Jul. 6, 2022 (KR) 10-2022-0083113

(51) Int. Cl. C23F 1/12; H10P 50/28

(52) U.S. Cl. CPC C23F 1/12; H10P 50/285

(57) ABSTRACT

An atomic layer etching method for a metal oxide film formed on a predetermined underlayer on a substrate, includes: a fluorination step for supplying fluorine-containing gas to react with the surface of the metal oxide film to form a fluorinated surface layer; and a chemical etching step for supplying chemical etching gas to the substrate to remove the fluorinated surface layer. By repeating a cycle comprising the fluorination step and the chemical etching step a predetermined number of times, a portion of the metal oxide film is removed, and the fluorinecontaining gas reacts with the underlayer to form a non-volatile passivation film.

### CROSS-REFERENCE TO PRIOR APPLICATIONS

This application is a National Stage Patent Application of PCT International Application No. PCT/KR2023/009514 (filed on Jul. 5, 2023), which claims priority to Korean Patent Application No. 10-2022-0083113 (filed on Jul. 6, 2022), which are all hereby incorporated by reference in their entirety.

### BACKGROUND

The present invention relates to a semiconductor etching process, and more specifically, to an atomic layer etching (ALE) process of a metal oxide film having a high etching selectivity with respect to an underlying layer.

As the ultra-high integration and ultra-miniaturization of semiconductor devices continue, not only the thicknesses of thin films but also the line widths (Critical Dimension, CD) of patterns are gradually decreasing. For instance, the thickness of conductive or dielectric films forming transistors in DRAM devices is becoming thinner, with the line width shrinking to below 5 nm. In the fabrication of semiconductor devices with such ultra-fine, ultra-thin patterns, conventional physical/chemical processes or plasma processes are not only challenging in terms of atomic-level control but also tend to cause issues such as surface damage. Consequently, the need for atomic scale processing is increasingly recognized, not only in deposition processes but also in etching processes.

In semiconductor device fabrication processes where the thicknesses of thin films can be controlled at the atomic or molecular layer level, atomic layer deposition (ALD) processes and atomic layer etching (ALE) processes are known. However, when the thickness of a thin film deposited by the ALD process is extremely thin, it becomes challenging to meet the required physical properties with such a film. This is because, when the deposited film is too thin below a certain thickness, its crystallinity deteriorates, resulting in poor properties such as leakage current characteristics. To prevent the degradation of such properties, the thickness of the deposited thin film must be maintained above a certain level. However, if the thin film becomes too thick, it becomes difficult to achieve the desired dielectric constant or capacitance.

Therefore, in order to reduce the thickness of the thin film below a certain level while still meeting the required physical properties, it is necessary to form a crystalline layer with good crystallinity to a certain thickness or more through a deposition process, and then use the ALE process to further thin the layer by removing the deposited layer at the atomic or molecular level. For example, Korean Patent Laid-Open Publication No. 2019-0136438, titled ‘Thin film Formation Method’ (Patent Document 1), discloses a method of forming a zirconium oxide film or an aluminum oxide film using the ALD process, followed by etching with the ALE process to produce a high-crystallinity thin film.

However, when etching a thin film using the aforementioned ALE process, there is a possibility that other thin films that should not be etched are either etched or damaged during the etching of the target film. If undesired etching or surface damage of other thin films occurs during the etching process, it can lead to defects in the semiconductor device. This issue becomes even more likely when the process gas is plasma-activated to ensure reactivity.

For example, in the manufacturing of certain semiconductor devices, such as the capacitor of a DRAM device, a process has been proposed in which a deposition process (e.g., ALD) and ALE process are sequentially applied to form a high-k dielectric metal oxide film with excellent crystallinity while maintaining a reduced thickness. In this case, the metal oxide film is deposited on a predetermined underlayer, such as a titanium nitride (TiN) layer, during the deposition process, such as ALD. Then, the ALE process is applied to thin the deposited metal oxide film.

In this process sequence, there is a possibility of causing surface damage to the metal oxide film and/or the underlying layer being etched along with it during the ALE process. Specifically, Korean Patent Laid-Open Publication No. 2019-0142407, titled ‘In-Situ Selective Deposition and Etching for Advanced Patterning Applications’ (Patent Document 2), discloses that in an ALE process using the same etching gas, titanium nitride films are also considered as etching targets in addition to metal oxide films such as zirconium oxide films and hafnium oxide films. Accordingly, in the ALE process using this etching gas, the titanium nitride underlayer can easily be etched away while the metal oxide film is being etched.

### PRIOR ART

Korean Patent Laid-Open Publication No. 2019-0136438
Korean Patent Laid-Open Publication No. 2019-0142407

### SUMMARY

The objective of the present invention is to provide an ALE process for etching single or composite metal oxide films, such as zirconium oxide, hafnium oxide, and hafnium zirconium oxide, without causing etching of the underlying layer and without inducing surface damage or similar issues on the metal oxide film, which is the target layer for etching.

One embodiment of the present invention for solving the above objective provides a method for atomic layer etching of a metal oxide film formed on a predetermined underlayer on a substrate. This method comprises: a fluorination step of supplying a fluorine-containing gas to react with the surface of the metal oxide film to form a fluorinated surface layer; and a chemical etching step of supplying a chemical etching gas to the substrate to remove the fluorinated surface layer, wherein by repeating a cycle that includes the fluorination step and the chemical etching step a predetermined number of times, a portion of the metal oxide film is removed, and the fluorine-containing gas reacts with the underlayer to form a non-volatile passivation layer.

According to one aspect of the embodiment, the fluorine-containing gas is in a non-plasma state, and the process temperature of the fluorination step may be 200-500° C. Preferably, the process temperature of the fluorination step may be 300-400° C.

According to another aspect of the embodiment, the fluorine-containing gas may include one or more gases selected from the group consisting of HF gas, NF3 gas, F3NO gas, and FNO gas, and the underlayer may be a titanium nitride film. In this case, the HF gas may be anhydrous HF gas. The non-volatile passivation layer may include one or more of titanium difluoride (TiF₂) and titanium trifluoride (TiF₃). Additionally, the chemical etching gas may include one or more gases selected from the group consisting of TiCl₄ gas and SiCl₄ gas.

According to another aspect of the embodiment, the metal oxide film may include one or more oxide films selected from the group consisting of hafnium oxide film, zirconium oxide film, and hafnium zirconium composite oxide film.

According to the above-described embodiments of the present invention, in the etching process of a metal oxide film using the ALE process, by using a fluorine-containing gas that reacts with the underlayer of the metal oxide film to form a non-volatile passivation layer and/or a gas with relatively large molecular size, it is possible to control reactivity and suppress gas diffusion through grain boundaries of the metal oxide film. As a result, the metal oxide film can be etched with a high selectivity ratio relative to the underlying layer.

### BRIEF DESCRIPTION OF THE DRAWINGS

FIGS. 1a and 1b are transmission electron microscope images showing experimental results according to a conventional plasma ALE process.

FIGS. 1c and 1d are transmission electron microscope images showing experimental results according to a conventional plasma ALE process at low temperatures.

FIG. 1e is a transmission electron microscope image showing experimental results according to a conventional thermal plasma ALE process.

FIG. 2 is a schematic diagram illustrating the etching process according to a conventional ALE process.

FIG. 3 is a schematic diagram illustrating the ALE etching process according to an embodiment of the present invention.

FIG. 4 is a flowchart illustrating a method for atomic layer etching of a metal oxide film according to one embodiment of the present invention.

FIGS. 5a to 5c are cross-sectional schematic views illustrating the state at each step of the atomic layer etching method shown in FIG. 4.

FIG. 6 is transmission electron microscope images showing an experimental result according to the ALE etching process of an embodiment of the present invention.

### DETAILED DESCRIPTION

Hereinafter, embodiments of the present invention will be described in detail with reference to the accompanying drawings. The terms and words used in this specification have been selected in consideration of the functions in the embodiments, and the meanings of these terms may vary depending on the intent of the invention or customary usage. Therefore, terms used in the following embodiments, when specifically defined in this specification, shall follow those definitions; otherwise, they should be interpreted according to the meanings generally understood by those skilled in the art.

Atomic layer etching (ALE) is a film etching technique utilizing sequential, self-limiting reactions, enabling etching control at the atomic layer level by reacting only at the surface of the target layer. When applying the ALE process to etch high-k dielectric metal oxide films, such as a hafnium oxide film, a zirconium oxide film, or a hafnium zirconium composite oxide film, which are used as high-k dielectric layers in semiconductor devices, such as DRAM, it is essential to ensure not only the self-limiting characteristic required for atomic-layer-level etching, but also to avoid causing surface damage to the metal oxide film and/or etching the underlying layer. In other words, it is necessary to control the reactivity of the ALE process for the metal oxide film (atomic-layer-level etching), while also achieving a high etching selectivity ratio with respect to the underlying layer.

In the etching process of a metal oxide film using the ALE process, at least two reaction mechanisms are known. The first reaction mechanism is the direct chlorination reaction, in which the metal oxide film is removed by direct reaction with a chlorine-containing gas. In this case, the chlorine-containing gas may be supplied in either a non-plasma state or a plasma state. In the former case, even when the process temperature is raised to 500° C., the reaction rate remains low, making it difficult to etch the metal oxide film effectively. In contrast, in the latter case, the reactivity increases proportionally with the process temperature, allowing effective etching of the metal oxide film; however, the chlorine-containing gas in the plasma state becomes overly reactive, making it challenging to control etching at the atomic layer level.

The second reaction mechanism involves modifying, or fluorinating, the surface of the metal oxide film by reacting it with a fluorine-containing gas, followed by a ligand exchange using a chemical etching gas to convert it into a material that can evaporate at relatively low temperatures, thereby removing it. In this case, the fluorine-containing gas may be supplied in a non-plasma state (hereinafter referred to as ‘thermal ALE’) or in a plasma state (hereinafter referred to as ‘plasma ALE’). However, as will be described below, in the case of plasma ALE, the reactivity of the plasma-activated gas is relatively higher than when supplied in a non-plasma state, which can lead to surface damage to the metal oxide film and/or make atomic-layer-level etching control more challenging.

However, according to the above second reaction mechanism, as disclosed in Korean Patent Laid-Open Publication No. 2019-0142407 (Patent Document 1), depending on the type of fluorine-containing gas and/or chemical etching gas used, there may be an issue where the underlying layer is also etched along with the metal oxide film. This will be described in more detail below, based on experimental results.

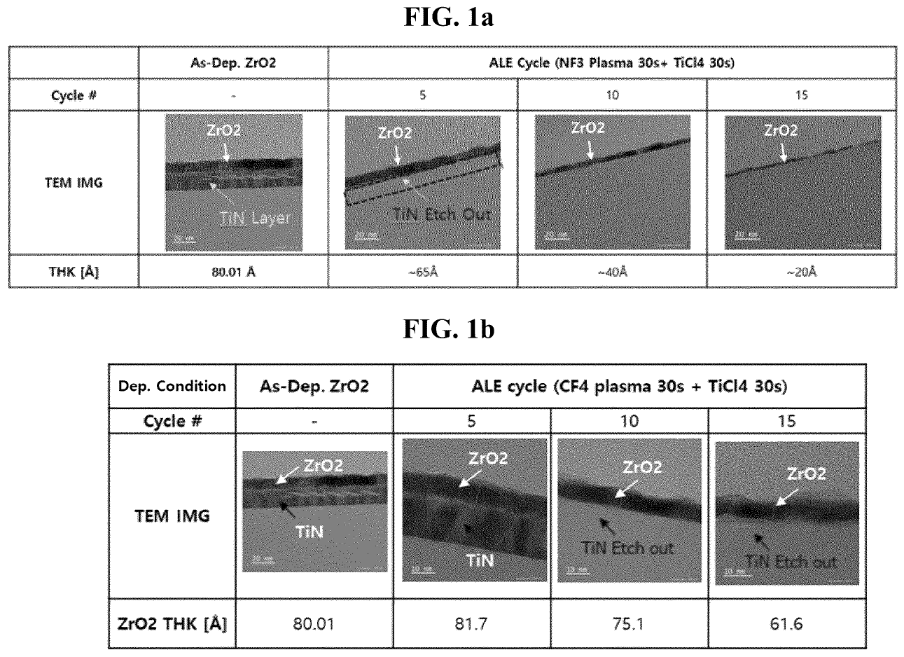

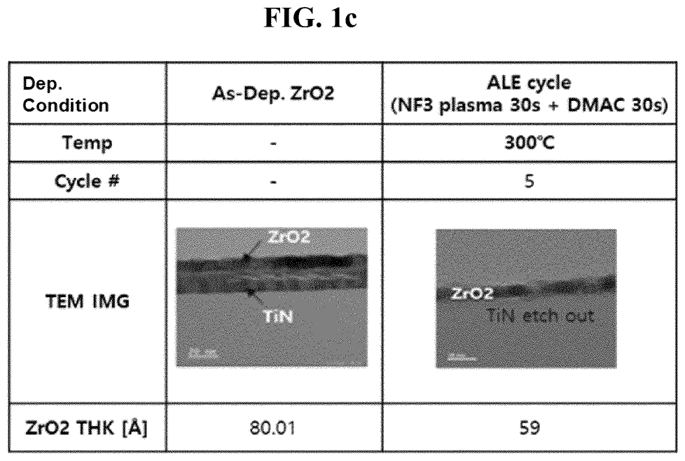

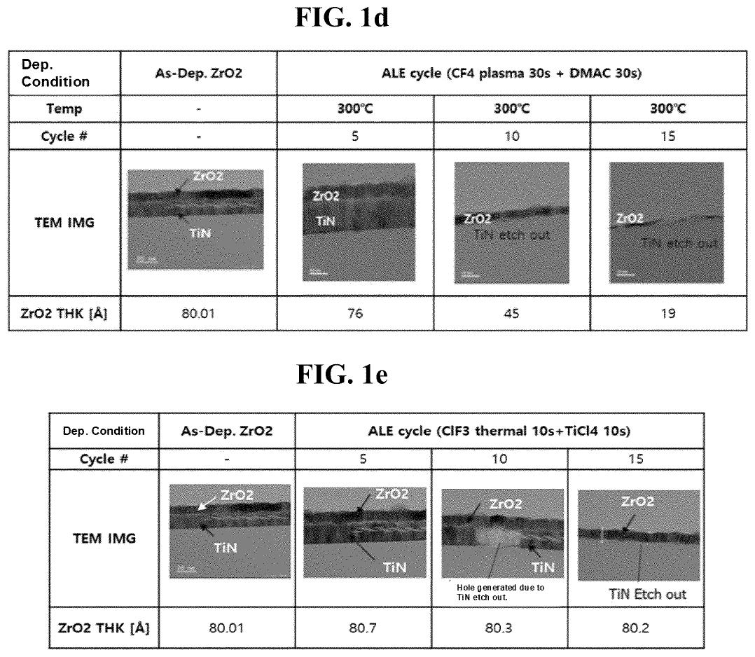

FIGS. 1a and 1b are transmission electron microscopy (TEM) images showing the phenomenon where the underlying titanium nitride film is also etched when a zirconium oxide film is etched using a plasma ALE process. In FIG. 1a, plasma NF₃ gas is used as the fluorine-containing gas and TiCl₄ gas as the chemical etching gas, while in FIG. 1b, plasma CF₄ gas is used as the fluorine-containing gas, with TiCl₄ gas again used as the chemical etching gas.

Referring to FIG. 1a, when an ALE process cycle is conducted by supplying plasma NF₃ gas for 30 seconds, followed by TiCl₄ gas for 30 seconds, and repeated 5, 10, and 15 times, it can be observed that an approximately 80 Å-thick zirconium oxide film is etched down to about 65 Å, 40 Å, and 20 Å, respectively, while the underlying titanium oxide film is etched away. Referring to FIG. 1b, when an ALE process cycle is conducted by supplying plasma CF₄ gas for 30 seconds, followed by TiCl₄ gas for 30 seconds, and repeated 5, 10, and 15 times, it can be observed that an approximately 80 Å-thick zirconium oxide film is etched down to about 80 Å, 75 Å, and 62 Å, respectively, and after 10 cycles, the underlying titanium oxide film is etched away.

FIGS. 1c and 1d are transmission electron microscopy (TEM) images showing the phenomenon where the underlying titanium nitride film is also etched when a zirconium oxide film is etched using plasma ALE, with the process temperature set to approximately 300° C. In FIG. 1c, plasma NF₃ gas is used as the fluorine-containing gas and DMAC gas as the chemical etching gas, while in FIG. 1d, plasma CF₄ gas is used as the fluorine-containing gas and DMAC gas as the chemical etching gas.

Referring to FIG. 1c, when an ALE process cycle is conducted by supplying plasma NF₃ gas for 30 seconds, followed by DMAC gas for 30 seconds, and repeated 5 times, it can be observed that an approximately 80 Å-thick zirconium oxide film is etched down to about 59 Å, while the underlying titanium oxide film is etched away. Referring to FIG. 1d, when an ALE process cycle is conducted by supplying plasma CF₄ gas for 30 seconds, followed by DMAC gas for 30 seconds, and repeated 5, 10, and 15 times, it can be observed that an approximately 80 Å-thick zirconium oxide film is etched down to about 76 Å, 45 Å, and 19 Å, respectively, and that after 10 cycles, the underlying titanium oxide film is etched away.

FIG. 1e is a transmission electron microscopy (TEM) image showing the phenomenon where the underlying titanium oxide film is etched when a zirconium oxide film is etched using thermal ALE. In this case, ClF₃ gas is used as the fluorine-containing gas and TiCl₄ gas as the chemical etching gas. Referring to FIG. 1e, when an ALE process cycle is conducted by supplying ClF₃ gas for 10 seconds, followed by TiCl₄ gas for 10 seconds, and repeated 5, 10, and 15 times, it can be observed that the titanium nitride film begins to be etched from around the 10th cycle and is almost entirely removed after 15 cycles. However, in the experimental example of FIG. 1e, even after 15 ALE cycles, the approximately 80 Å-thick zirconium oxide film remains almost unetched, likely because the ligand exchange reaction of the generated ZrF₄ does not proceed effectively at the low process temperature of 300° C.

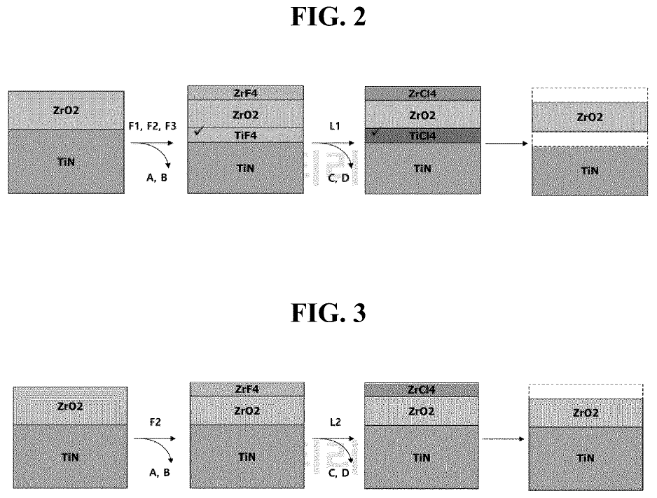

FIG. 2 is a schematic diagram illustrating the process in which the underlying layer is etched along with the metal oxide film (e.g., a zirconium oxide film) when using a conventional ALE process, as shown in the experimental results of FIGS. 1a through 1e. In FIGS. 2, A, B, C, and D represent reaction by-products generated in the corresponding reactions. Referring to FIG. 2, when plasma NF₃ gas, plasma CF₄ gas, or ClF₃ gas is used as the fluorine-containing gas, it reacts with the zirconium oxide film to form TiF₄ (boiling point: approximately 400° C. or higher). Subsequently, when TiCl₄ gas or DMAC gas is supplied as the chemical etching gas, the TiF₄ undergoes ligand exchange, converting to TiCl₄ (boiling point: approximately 136° C. or higher), which evaporates at a relatively low temperature, resulting in the etching of the titanium nitride film along with the zirconium oxide film. In this manner, the etching of the titanium nitride underlayer beneath the zirconium oxide film occurs because the zirconium oxide film reacts with the fluorine-containing gas to form TiF₄, which fails to function as a passivation layer.

Based on the above experimental results, it is anticipated that using materials (fluorine-containing gases and/or chemical etching gases) that react with the metal oxide film but inhibit or suppress reactions with a underlying layer, such as a titanium nitride film, could enhance the etching selectivity. More specifically, by suppressing or minimizing gas diffusion through the grain boundaries of the metal oxide film, it becomes possible to block or limit the contact of the fluorine-containing gas with the underlying titanium nitride film. Furthermore, by controlling the reactivity of the fluorine-containing gas so that it forms a passivation layer even when it reacts with the underlayer, it is possible to prevent or suppress the etching of the titanium nitride film by the chemical etching gas. As will be discussed further below, according to the present invention, when using relatively large fluorine-containing gases, such as HF gas, NF₃ gas, F₃NO gas, or FNO gas, it is possible to block or suppress gas diffusion through the grain boundaries of the metal oxide film. Additionally, controlling the reactivity enables the formation of a passivation layer, which can prevent or minimize the etching of the underlying layer, such as the titanium nitride film. Furthermore, using chemical etching gases that produce by-products with sufficient vapor pressure after the reaction, such as TiCl₄ gas or SiCl₄ gas, prevents a decrease in the etching rate or the cessation of etching of the metal oxide film due to residual reaction by-products in the process chamber.

FIG. 3 is a schematic diagram illustrating the process in which the underlying titanium nitride film is not etched, as it does not react with the fluorine-containing gas, when etching a metal oxide film (e.g., zirconium oxide film) using a thermal ALE process with HF gas as the fluorine-containing gas. In FIGS. 3, A, B, C, and D all represent reaction by-products. Referring to FIG. 3, when HF gas is used as the fluorine-containing gas, it reacts with the zirconium oxide film to form ZrF₄, but does not react, or only minimally reacts, with the underlying titanium nitride film. Consequently, it can be seen that when TiCl₄ gas is subsequently supplied as the chemical etching gas, ZrF₄ undergoes ligand exchange to form highly volatile ZrCl₄ and is thereby removed, while the titanium nitride film does not react with TiCl₄ and remains unetched.

According to an embodiment of the present invention, when the reactivity of the fluorine-containing gas can be controlled, it is possible to create a relatively fluorine-deficient environment, so that even if the fluorine-containing gas reacts with the titanium nitride film, it can be controlled to predominantly produce TiF₂ and/or TiF₃ instead of TiF₄. Notably, TiF₂ and TiF₃ have boiling points of 2152° C. and 1400° C., respectively, and thus are virtually non-volatile at the ALE process temperature (e.g., 400° C. or below). As a result, TiF₂ and TiF₃, which are reaction products between the fluorine-containing gas and the titanium nitride film, can act as a passivation layer, preventing further reactions between the titanium nitride film and the fluorine-containing gas in subsequent cycles. Therefore, according to this embodiment of the present invention, it is possible to etch the metal oxide with high selectivity relative to the titanium nitride film.

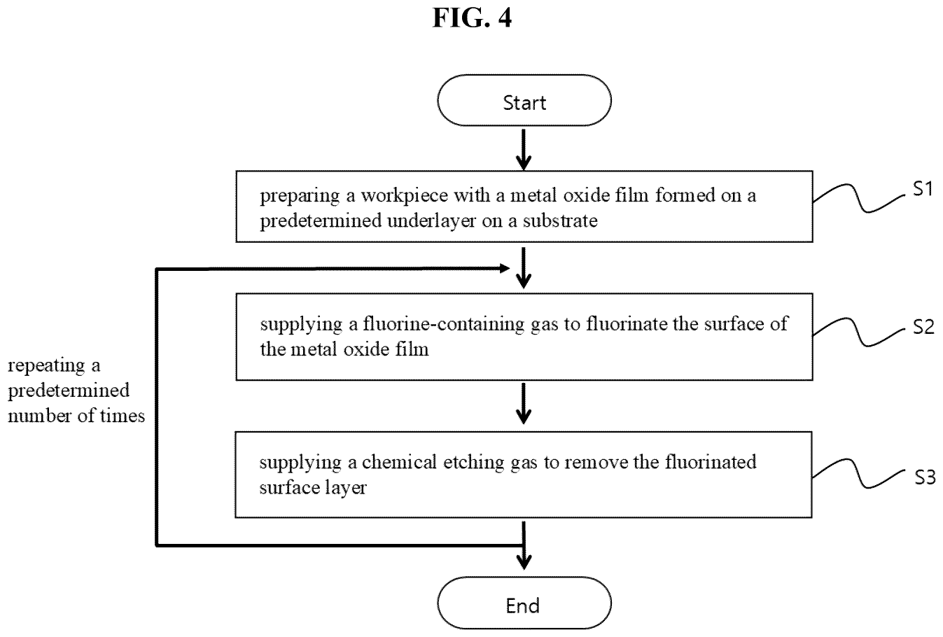

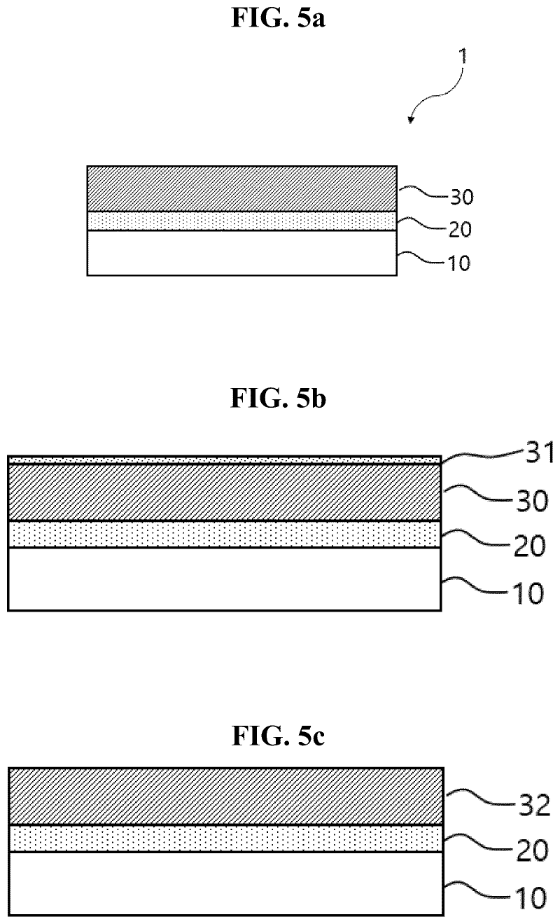

FIG. 4 is a flowchart illustrating a method for an atomic layer etching of a metal oxide film according to one embodiment of the present invention, and FIGS. 5a to 5c are cross-sectional schematic views illustrating the state during each step of the atomic layer etching method shown in FIG. 4.

Referring to FIGS. 4 and 5a, a workpiece 1 is prepared with a metal oxide film 30 formed on a predetermined material layer (a underlayer 20) on a substrate 10 (Step S1). For example, this step may involve loading the workpiece 1 onto a support inside a process chamber to perform the ALE process. Alternatively, in a system where the ALD and ALE processes are conducted in-situ, this step may involve preparing to start the ALE process after completing the deposition of the metal oxide film 30 on the underlayer 20 on the substrate 10 via the ALD process in a single process chamber. This workpiece 1 schematically represents a structure similar to that of a semiconductor device, such as one used in DRAM manufacturing. The upper surface of the metal oxide film 30 serves as the surface to be processed, which is then etched and removed at the atomic layer level through the subsequent ALE process.

Here, the substrate 10 is a semiconductor wafer, such as a silicon wafer, but is not limited thereto. Additionally, the underlayer 20 does not necessarily have to be formed directly on the substrate 10, and one or more material layers may be interposed in between. The interposed material layer may be an insulating layer and/or a conductive layer, with no specific limitations on its type or the number of layers. For example, the underlayer 20 may be a titanium nitride film formed on the upper side of a conductive layer used as a lower electrode, as part of a capacitor element in DRAM.

In this embodiment, the metal oxide film 30 may be selected from the group consisting of HfO₂, ZrO₂, HfZrO₂, Al₂O₃, Y₂O₃, La₂O₃, Ta₂O₅, and combinations thereof. Preferably, the metal oxide film 30 is selected from the group consisting of HfO₂, ZrO₂, HfZrO₂, and combinations thereof. It is desirable for the metal oxide film 30 to be a crystallographically stabilized film capable of exhibiting at least high-k dielectric properties, and it is advantageous if the crystallinity of the film is maintained even when a portion of the metal oxide film 30 is etched and removed particularly through the ALE process described below.

In this embodiment, there is no particular limitation on the method for forming the metal oxide film 30. For example, the metal oxide film 30 may be formed by a known ALD process or by other deposition processes, such as plasma-enhanced chemical vapor deposition (PECVD), rather than ALD. The thickness of the metal oxide film 30 is also not specifically limited; however, it should be greater than the final desired thickness of the film to remain after the ALE process (for example, less than 5 nm in the case of a high-k dielectric oxide film for a DRAM capacitor). For instance, the thickness of the metal oxide film 30 may be greater than 5 nm and up to 30 nm.

Referring to FIGS. 4 and 5b, a fluorination process is performed on the metal oxide film 30 by supplying a process gas containing a fluorine-containing gas into the process chamber (S2). The fluorine-containing gas may be HF gas, NF₃ gas, F₃NO gas, FNO gas, or a combination thereof. In this step, the surface of the metal oxide film 30a is fluorinated by the supplied fluorine-containing gas, forming a fluorinated surface layer 31. For example, a zirconium oxide film (ZrO₂) can be fluorinated to form ZrF₄, a hafnium oxide film (HfO₂) can form HfF₄, and a hafnium zirconium composite oxide film (HfZrO₂) can form a fluorinated surface layer 31 of HfZrF₄.

On the other hand, in Step S2, the fluorine-containing gas does not react with the underlayer 20, or at least its reactivity is suppressed. This is because, as mentioned above, when a fluorine-containing gas with a relatively large molecular size, such as HF gas, NF₃ gas, F₃NO gas, or FNO gas, is used, diffusion into the titanium nitride underlayer 20 of the metal oxide film 30a can be blocked or suppressed.

In this embodiment, it is preferable that the fluorine-containing gas be supplied in a vaporized, gaseous state rather than in a plasma state. As noted above, fluorine-containing gas in a plasma state is highly reactive, making it more likely to react with the underlayer 20 of the metal oxide film 30a. In such cases, the surface of the underlayer 20 can become fully fluorinated (for example, the titanium nitride film would be fluorinated to TiF₄) and subsequently removed by the chemical etching gas supplied in the following step (Step S3). The vaporized fluorine-containing gas may be supplied on its own or together with a carrier gas, such as argon gas or nitrogen gas.

When the fluorine-containing gas is supplied, the internal temperature of the process chamber may be set between 200-500° C. to induce a reaction with the metal oxide film 30 or to increase the reaction rate. For example, the internal temperature of the process chamber can be adjusted to the desired range by heating the workpiece, including the substrate 10, via the substrate support and/or by using a carrier gas at the desired temperature. Preferably, the internal temperature of the process chamber is between 300-400° C. If the process temperature is below 300° C., the reaction rate may be too low, leading to longer processing times; on the other hand, if the process temperature exceeds 400° C., the fluorine-containing gas is more likely to react with the underlayer, forming a relatively volatile fluoride (e.g., TiF₄), which increases the likelihood of reaction with the underlayer.

According to one aspect of this embodiment, it is preferable that the HF gas among the fluorine-containing gases be vaporized from anhydrous hydrofluoric acid.

According to one aspect of this embodiment, when the reactivity of the fluorine-containing gas is controlled through a low-temperature process (e.g., 400° C. or below), even if the fluorine-containing gas reacts with the underlayer 20, such as a titanium nitride film, the resulting fluorides will be compounds with higher boiling points than TiF₄, such as TiF₂ or TiF₃. This is because, in Step S2, when the reactivity of the fluorine-containing gas is suppressed, an insufficient amount of fluorine is provided for a complete reaction with the titanium nitride film. Therefore, if the fluorine-containing gas reacts with the underlayer 20, such as a titanium nitride film, in Step S2, a non-volatile passivation layer of TiF₂ and/or TiF₃, which have relatively high boiling points, is formed. This non-volatile passivation layer adheres to the exposed surface of the titanium nitride film, thereby preventing HF gas from contacting and reacting with the titanium nitride film in subsequent steps.

Although not shown in the drawings, after supplying the fluorine-containing gas into the process chamber, an additional purge step may be performed in which a purge gas is supplied to the process chamber to remove any unreacted fluorine-containing gas, reaction by-products, and carrier gas. An inert gas, such as nitrogen gas or argon gas, can be used as the purge gas. If the carrier gas used in Step S2 is the same as the purge gas in the purge step, there is no need to add a separate means for supplying the purge gas; simply stopping the supply of the silicon precursor while continuing to supply the carrier gas to the vacuum chamber can accomplish the purge process.

Referring to FIGS. 4 and 5c, a chemical etching gas is supplied into the process chamber to replace the fluorine in the fluorinated surface layer 31 with another element, such as chlorine, and remove it (S3). At this time, compounds in the fluorinated surface layer 31, such as ZrF₄, HfF₄, and/or HfZrF₄, undergo ligand exchange to form ZrCl₄, HfCl₄, and/or HfZrCl₄. The reaction products in Step S3, such as ZrCl₄, HfCl₄, and/or HfZrCl₄, have lower boiling points and are therefore more volatile than the original reactants, ZrF₄, HfF₄, and/or HfZrF₄. Consequently, the fluorinated surface layer 31, now replaced with chlorine, can be etched and removed.

According to one aspect of this embodiment, there is no particular limitation on the type of chemical etching gas. For example, the chemical etching gas may be DMAC, TiCl₄, or the like. These chemical etching gases generate by-products with sufficient vapor pressure compared to other gases, which minimizes the residual by-products on the fluorinated surface layer 31, thereby preventing the fluorinated surface layer 31 from not being etched due to the by-products. Preferably, the chemical etching gas is TiCl₄.

Although not shown in the drawings, a purge gas is supplied into the process chamber to exhaust any remaining chemical etching gas, reaction by-products, carrier gas, and the like to the outside of the process chamber. Accordingly, one cycle of the atomic layer etching (ALE) process for etching the metal oxide film 30 is completed, leaving a metal oxide film 32 with a reduced thickness.

The ALE process cycle, including the aforementioned Steps S2 and S3, is then repeated a predetermined number of times until the metal oxide film 32 is etched to the desired thickness. At this time, as the number of cycles increases, the amount of the metal oxide film 32 that is etched away increases, ultimately leaving a metal oxide film with the desired thickness.

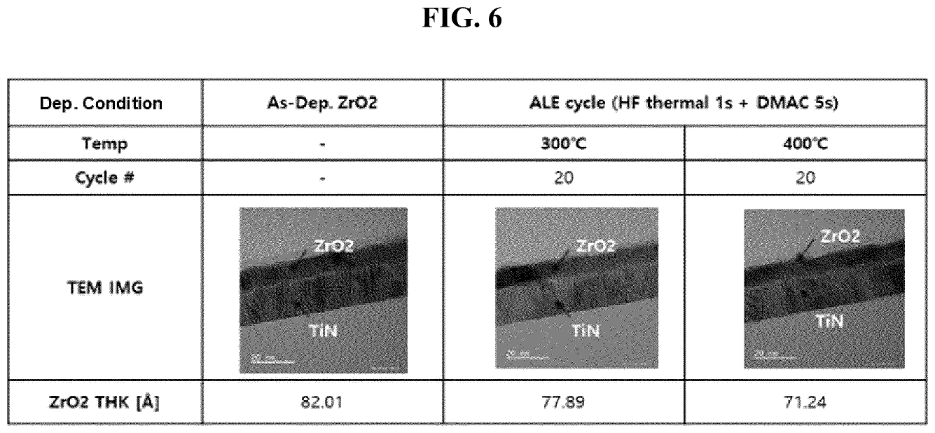

FIG. 6 is a transmission electron microscopy (TEM) image showing a phenomenon in which a titanium nitride film thereunder is etched when a zirconium oxide layer is etched using a thermal ALE process according to an embodiment of the present invention, wherein HF gas is used as the fluorine-containing gas, and TiCl₄ gas is used as the chemical etching gas. The temperature in the process chamber is set to 300° C. and 400° C., respectively. Referring to FIG. 6, when the ALE process cycle supplying HF gas for 1 second followed by TiCl₄ gas for 2 seconds is repeated 20 times, it can be seen that the zirconium oxide film is etched, while the titanium nitride film is almost unaffected. However, the etching rate of the zirconium oxide film is higher when the process chamber temperature is set to 400° C. compared to 300° C.

As described in detail above, in the embodiment of the present invention, a thermal ALE process is applied to etch metal oxide films such as hafnium oxide films, zirconium oxide films, and/or hafnium zirconium composite oxide films, with the goal of controlling the etching rate of the metal oxide film and preventing the etching of underlying material layers, such as a titanium nitride film. In particular, in the thermal ALE process, the surface is modified using a fluorine-containing gas, followed by the removal of the modified surface layer with a chemical etching gas. The fluorine-containing gas may be HF, NF₃, F₃NO, or FNO, while the chemical etching gas may be TiCl₄ or SiCl₄. As can be seen from the experimental results described above, the fluorine-containing gases used in the thermal ALE process can inhibit diffusion into the underlying layer through the grain boundaries of the metal oxide film and, unlike other materials, allow for the formation of a passivation layer through controlled reactivity. Therefore, according to this embodiment of the present invention, it is possible to etch the metal oxide film with a high selectivity relative to the underlying layer, effectively preventing or suppressing the etching of the underlying layer.

Although the present invention has been described in detail with reference to the preferred embodiments, the present invention is not limited to the above-described embodiment, and various modifications may be made by those skilled in the art within the scope of the technical idea of the present disclosure.

The present invention may be applied to a semiconductor manufacturing process.

1. A method for atomic layer etching of a metal oxide film formed on a predetermined underlayer on a substrate, comprising:
a fluorination step of supplying a fluorine-containing gas to react with the surface of the metal oxide film to form a fluorinated surface layer; and
a chemical etching step of supplying a chemical etching gas to the substrate to remove the fluorinated surface layer,
wherein a cycle including the fluorination step and the chemical etching step is repeated a predetermined number of times to remove a portion of the metal oxide film, and
the fluorine-containing gas reacts with the underlayer to form a non-volatile passivation layer.

2. The method for atomic layer etching of a metal oxide film according to claim 1, wherein the fluorine-containing gas is in a non-plasma state, and a process temperature of the fluorination step is 200-500° C.

3. The method for atomic layer etching of a metal oxide film according to claim 2, wherein the process temperature of the fluorination step is 300-400° C.

4. The method for atomic layer etching of a metal oxide film according to claim 1, wherein the fluorine-containing gas includes one or more gases selected from the group consisting of HF gas, NF₃ gas, F₃NO gas, and FNO gas, and
the underlayer is a titanium nitride film.

5. The method for atomic layer etching of a metal oxide film according to claim 4, wherein the HF gas is anhydrous HF gas.

6. The method for atomic layer etching of a metal oxide film according to claim 4, wherein the non-volatile passivation layer includes one or more of titanium difluoride (TiF₂) and titanium trifluoride (TiF₃).

7. The method for atomic layer etching of a metal oxide film according to claim 4, wherein the chemical etching gas includes one or more gases selected from the group consisting of TiCl gas and SiCl₄ gas.

8. The method for atomic layer etching of a metal oxide film according to claim 1, wherein the metal oxide film includes one or more oxide films selected from the group consisting of hafnium oxide film, zirconium oxide film, and hafnium zirconium composite oxide film.
